(19) United States
(12) Patent Application Publication
(10) Pub. No.: US 2020/0161486 A1
(43) Pub. Date: May 21, 2020

(54) METHOD AND APPARATUS FOR CHANNELING LIGHT FOR STACKED SOLAR CELL

(71) Applicant: Kyocera Document Solutions Inc., Osaka (JP)

(72) Inventor: Eric Pugh, Torrance, CA (US)

(73) Assignee: Kyocera Document Solutions Inc.

(21) Appl. No.: 16/197,327

(22) Filed: Nov. 20, 2018

(51) Int. Cl. H01L 31/043; G06F 1/18; G06F 1/16; H01L 31/05

(52) U.S. Cl. CPC H01L 31/043; G06F 1/188; H01L 31/05; G06F 1/1605; G06F 1/182

(57) ABSTRACT

A multifunctional peripheral with a solar powered display screen which includes a plurality of solar cell assemblies, each solar cell assembly including a plurality of solar cells and a plurality of transparent separators, where each solar cell assembly is arranged so that the solar cells are stacked on top of one another, with a transparent separator in between each pair of solar cells, and where each transparent separator has a rectangular shape when viewed in a plan view.

### FIELD OF THE INVENTION

The present disclosure relates to a multifunctional peripheral using a solar powered display.

### BACKGROUND

Power failure from the power grid, or brownouts, or local power failure of a building or block has long been a problem. High demand on a power grid combined with aging power grid infrastructure can lead to regular power failures over high-demand summer months. Further, with the use of motors, largely to run air conditioning compressors, the power factor of the power grid can become too low to support electric motors and other electronic devices in what is known as a brownout. Additionally, in winter months, snow storms and other weather events can often disable local power lines with branches falling from trees and high wind damaging the grid.

The above problems have been known for some time and various solutions to these problems have been put forth. For example, an uninterruptible power supply (UPS) has been used in an attempt to address power failures. Further, battery banks for backup power have also been used.

Solar energy has also gained attention as a way to ease demand on the power grid by providing maximum power during the daytime hours, when grid demand is at its peak. Using large solar arrays on top of buildings can supply an entire building with at least part of its power requirement. Further, it has been known to power small electronic devices such as watches and calculators with solar cells.

To this end, it is desirable to increase the efficiency of the individual solar cell and the solar array as a whole. This can be done in a number of ways, such as by integrating small metallic studs into the semiconductor substrate. This alters the path of the light so that more light is captured and directed toward the solar cell. However, this structure requires specially designed semiconductors to accommodate the metallic studs and provide the efficiency increase. This leads to an increase in cost and an overall lower utilization of solar cells and solar cell arrays.

### SUMMARY

The present disclosure provides a multifunctional peripheral (MFP). The MFP can have a solar powered display screen, which functions as a control panel of the MFP, and the solar powered display screen can include a solar cell array which can include a plurality of solar cell assemblies, where each solar cell assembly can include a plurality of solar cells and a plurality of transparent separators; wherein the solar cells are stacked on top of one another, with a transparent separator in between each pair of solar cells; and wherein each transparent separator has a generally rectangular shape when viewed in a plan view.

The present disclosure also provides a solar powered display screen with a plurality of solar cell assemblies, where each solar cell assembly can include a plurality of solar cells and a plurality of transparent separators; wherein the solar cells are stacked on top of one another, with a transparent separator in between each pair of solar cells; and wherein each transparent separator has a generally rectangular shape when viewed in a plan view.

The present disclosure further provides a multifunctional peripheral which can include a solar powered display screen functioning as a control panel; and a plurality of solar cell assemblies, where each solar cell assembly can include a plurality of solar cells, and a plurality of transparent separators; wherein the solar cells are stacked on top of one another, with a transparent separator in between each pair of solar cells; wherein each transparent separator has a generally square or rectangular shape when viewed in a plan view; wherein each transparent separator has a reflecting surface which is configured to reflect light toward a surface of the solar cell which is below it; and wherein the plurality of solar cell assemblies is configured to output a voltage and a current that are sufficient to meet a voltage requirement and a current requirement of the solar powered display screen.

### BRIEF DESCRIPTION OF THE DRAWINGS

The following drawings illustrate examples of various components of embodiments of the invention disclosed herein, and are for illustrative purposes only.

FIG. 1 shows a perspective view of a stack of solar cells and transparent separators;

FIG. 2 shows a cross sectional view of a transparent separator according to a first embodiment;

FIG. 3 shows a plan view of a transparent separator according to a second embodiment;

FIG. 4 shows a cross-sectional view of a transparent separator according to a second embodiment;

FIG. 5 shows a plan view of a transparent separator according to a third embodiment;

FIG. 6 shows a first cross-sectional view of a transparent separator according to a third embodiment;

FIG. 7 shows a second cross-sectional view of a transparent separator according to a third embodiment;

FIG. 8A shows a plan view of an embodiment of a transparent separator with air gap standoffs;

FIG. 8B shows a cross-sectional view of an embodiment of a transparent separator with air gap standoffs;

FIG. 8C shows a cross-sectional view of another embodiment of a transparent separator with air gap standoffs;

FIG. 8D shows a cross-sectional view of an embodiment of a transparent separator with air gap standoffs and a solar cell; and

FIG. 9 shows a display screen being powered by an array of solar cell assemblies using a minimal area.

### DETAILED DESCRIPTION

The illustrative block diagrams and flowcharts depict process steps or blocks that may represent assemblies, segments, or portions of code that include one or more executable instructions for implementing specific logical functions or steps in the process. Although the particular examples illustrate specific process steps or procedures, many alternative implementations are possible. Some process steps may be executed in different order from the specific description herein based on, for example, considerations of function, purpose, conformance to standard, legacy structure, user interface design, and the like.

In order to reduce the load on a backup system such as an uninterruptible power supply (UPS) or battery bank during a power failure, or for situations where no such system exists, the inventors have created a solar powered display screen which has a minimum form factor while still allowing complete and continuous use of the display screen.

However, solar cell technology is not to the point where a single, small cell can power a display device, such as that used on a MFP, copy machine, etc. As such, in order to power a display screen, multiple solar cells must be used together to achieve the necessary power requirements of a display screen. While a large solar cell could conceivably power a display screen, this is impractical as the area for the solar cell would be so large that it couldn't be used indoors and couldn't be positioned on an MFP or copy machine.

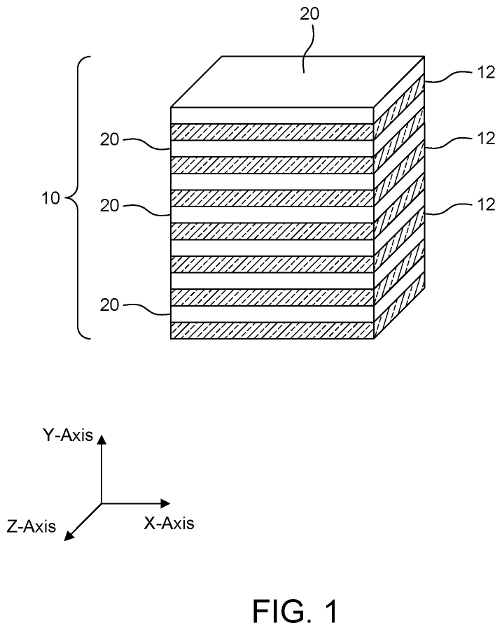

Therefore, with these layout constraints, a solution is to stack the solar cells on top of each in a vertical direction, as shown in FIG. 1. However, a problem occurs as to how to ensure that solar panels beneath the top panel, receive an adequate amount of lighting.

In light of the above issues, the inventors sought to increase the amount of light able to be received by the middle and bottom solar cells, thereby greatly increasing the efficiency of the solar cell stack and allowing a minimal form factor for powering a display. A transparent separator 20, as shown in FIG. 1 can be used to guide ambient light to the surface of a solar cell.

FIG. 1 shows a perspective view of a set of solar cells 12 and transparent separators 20. The solar cells 12 and transparent separators 20 can have a similar, approximately shape so that they can be stacked together, as shown in FIG. 1. Combined, the solar cells 12 and transparent separators 20 form a solar cell assembly 10. Each solar cell 12 in the assembly 10 is capable of outputting a specific voltage and current.

By combining a plurality of solar cells either in series and/or parallel, a desired voltage output and current output can be achieved. Specifically, by combining several solar cells in series, it is possible to add the voltage of each solar cell together to thereby increase the voltage to a desired amount. Further, by combining several solar cells in parallel, it is possible to add the current produced by each solar cell to thereby increase the current to a desired amount.

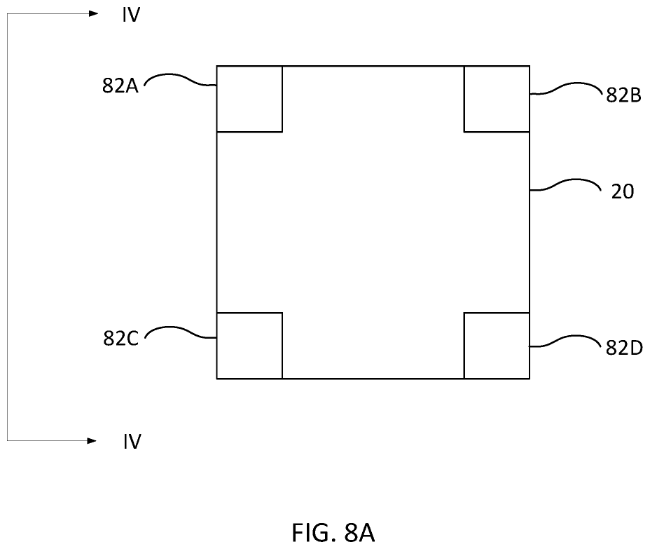

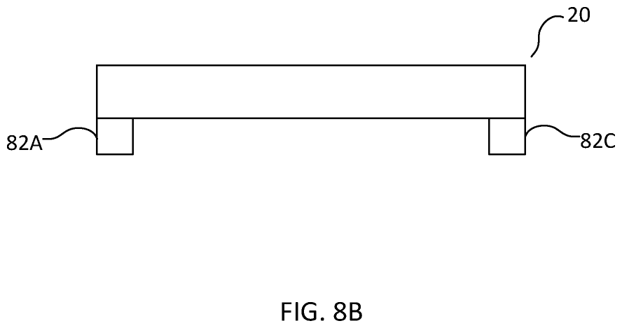

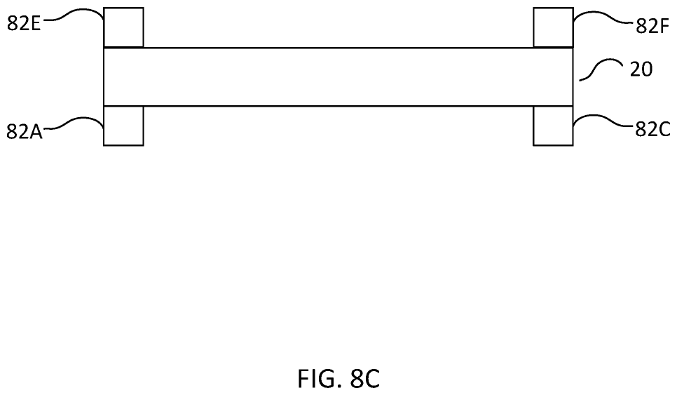

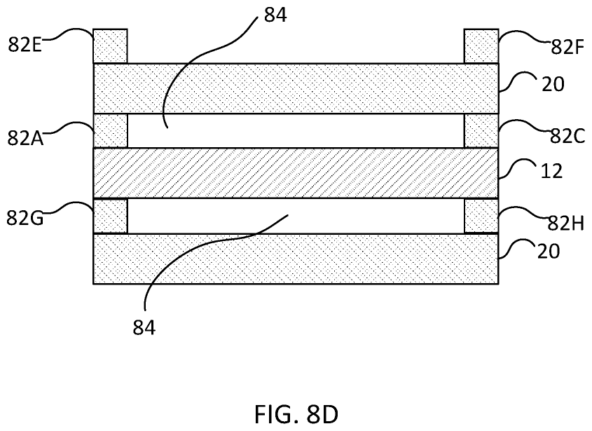

The solar powered display screen uses a solar cell array 90 which can be positioned around the display screen, for example, and as shown in FIG. 8, to achieve the necessary current and voltage requirements of the display screen. The solar cell array 90 is comprised of a plurality of solar cell assemblies 10, as shown in FIG. 1. Each solar cell assembly 10 includes two or more solar cells 12 and one or more transparent separators 50. The solar cells 12 supply continuous electrical power to the display screen, while the transparent separators channel light to the solar cells.

The display screen can be a part of a control panel, which controls a MFP or other office device. The display screen can be a touch screen using capacitance, resistance or other methods of determining where the user touched the screen. The display screen can allow the user to interact with and control the MFP functions. A MFP can mean a typical home use or commercial use MFP for an office environment. Here the use of the term office device encompasses a MFP, fax, copy machine, etc., including a multifunctional MFP (MFP) device which can perform one or more of the above functions.

### Solar Cell

Using a plurality of solar cells can increase both the voltage and current generating capabilities of the combined solar cells, but a problem arises that the area occupied by the solar cells becomes large. Therefore, stacking of solar cells and transparent separators into a solar cell assembly can produce the benefits of increased voltage and current, while keeping the size of the assembly to a minimum.

Given a single cell voltage of V_{cell}, and a total voltage of a single solar cells arranged in series V_{T}, where V_{cell}<V_{T}, a number of solar cells n, would have a voltage value of:

V_{T}=n×V_{cell} Formula 1:

Further, if the solar cells were stacked on top of one another and light passed through a medium, e.g. one or more transparent separators, to reach each individual solar cell, the voltage would be decreased by a transmittance coefficient T. This combination of solar cells and transparent separator(s) in a stacked configuration is referred to as a solar cell assembly. An example is shown in FIG. 1. Thus, the total voltage for the solar cell assembly would be:

V_{T}=n×V_{cell}×T Formula 2:

The total required voltage for a device to be powered V_{R}, can be a voltage for any number of devices, but in the example in the drawings, it is the total required voltage for a display unit. The value n should be chosen so as to ensure that V_{T}≥V_{R}. This ensures that enough voltage will be supplied to the device to powered.

Given a solar cell assembly current of I_{assembly}, and a total current required I_{R}, where I_{assembly}<I_{R}, a number of solar cell assemblies, m, would have a current value of:

Iₘ=m×T×I_{assembly} Formula 2:

The value m should be chosen so as to ensure that Iₘ≥I_{R}. The total current required I_{R} can be a current for any number of devices, but in the example in the drawings, it is the total required current for a display unit. The solar cell assemblies would be configured in parallel so that the cell currents are additive.

The solar cells 12 can be generally rectangular in shape, including a square shape. The generally rectangular solar cells 12 can also have the corner cut at a 45° angle. The solar cells could also have a generally circular shape. The shape of the solar cells in not limited except that it is preferable that the solar cells in a solar cell assembly 10 all have a generally consistent shape. Further, it is also preferable that the shape of the solar cells 12 generally matches that of the transparent separator.

### Transparent Separator

As discussed above, adding a number of solar cells together to increase voltage and/or current requirements can add to the size and space of the solar cell assembly. In order to reduce the size of the solar cell assemblies and channel light to the solar cells 12, transparent separation layers 20 can be used.

FIG. 1 shows a transparent separator 20 located in between two solar cells 12. By adding a transparent separation layer 20 in between the stacked solar cells, it is possible to increase the light that impinges on the solar cells 12. This allows the solar cells 12 to be stacked on top of each other, which reduces the product footprint of the solar cell assemblies, while also increasing the voltage and current generating capabilities of the solar cell assemblies.

Transparent separation layers 20 can be used to reduce the product footprint of a solar cell assembly by allowing the solar cells in the assembly to capture more light and produce more energy. The area of a typical transparent separation layer is usually the same or similar size as that of the solar cell that it is adjacent to. The width of a transparent separator can be varied, depending on design constraints such as the total height of the solar cell assembly, the cost of the material, the cost of assembling the solar cell assembly, etc.

Generally speaking, the height of a transparent separator can be a similar height as the solar cell which it is adjacent to. It is noted that the thicker the transparent separator is, the more light it can capture, but the higher the solar cell assembly may become. On the other hand, the thinner the transparent separator is, the less light it can capture, but the shorter the solar assembly can be.

One of the issues presented by using a transparent separation layer is how much light is able to be transmitted through it. This material property is known as transmittance. A high transmittance avoids a large transmission loss and avoids a large reduction of light intensity, as the light travels through a medium. A low transmittance incurs a large transmission loss and incurs a large reduction of light intensity, as the light travels through a medium. When light is attenuated by the transparent separator and has lower transmittance, it reduces the intensity of light that impinges on a solar cell. This reduces the energy output of the solar cell. Transmittance of light in a material is characterized by its transmittance T.

The transparent separator optical transmittance T, is less than 1.0 for any material. Some materials, such as fused quartz and fused silica, have an optical transmittance close to 1.0 at around 93% for light in the visible spectrum. However, fused quartz and fused silica can be expensive given the design constraints of powering a display screen.

Polycarbonate resin can also be used as material for the transparent separator. Polycarbonate resins are a group of thermoplastic polymers which contain carbonate groups in their chemical structure. These materials are very durable, easily worked, molded and thermoformed and can be optically transparent. Polycarbonate resins are also less expensive than fused quartz, but do have a lower transmittance value of light in the visible spectrum, around 90%.

Optically pure glass could also be used as the transparent separator. Optical glass can have a transmittance around 90%, depending on the level of purity.

The transmittance characteristics should also be optimized for the frequency or spectrum of light the solar cell is designed for. Thus, if the solar cell used had was designed for a light spectrum other than the visible light spectrum, such as ultraviolet or infrared, then a material used for the transparent separator having a high transmittance value in the desired frequency range could be used.

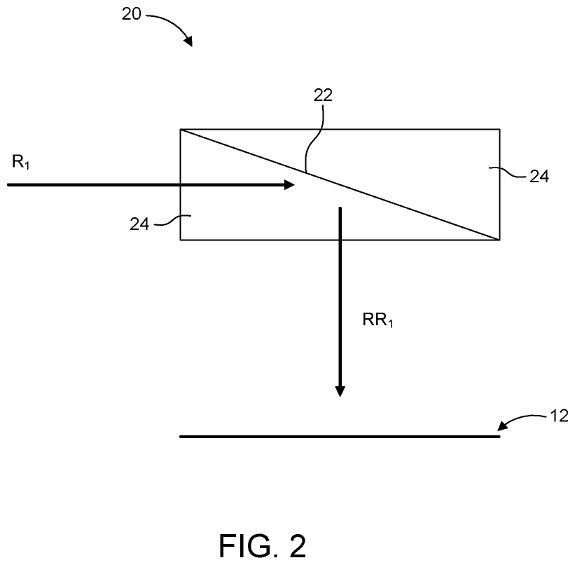

FIG. 2 shows a first embodiment of a transparent separator 20. Transparent separator 20 uses a transparent material 24, which can be made of fused quartz, fused silica, polycarbonate resin, optical glass, or any other suitable material having a high transmittance value. Preferably, the optical transmittance of the material used for the transparent separator is greater than 0.5 and as close to 1.0 as possible in the visible light spectrum.

Transparent separator 20 has a reflecting surface 22 within transparent material 24. Incoming light ray R₁ enters the transparent separator 20 for a left to right direction and reflects downward off of the reflecting surface 22. The reflected light ray RR₁ is traveling in a downward direction, which could be toward a surface of a solar cell. Reflecting surface 22 can be a metallic, mylar, or other reflective coating that can reflect incident light in the visual light spectrum.

Thus, the transparent separator 20 can be positioned in between two solar cells and the bottom solar cell can receive light that was originally traveling in a direction parallel to the surface of the solar cell, thereby increasing the efficiency of a solar cell assembly. That is, without the transparent separator 20, the light ray R₁ would not have impinged upon the solar cell 12, and would simply have passed over the solar cell.

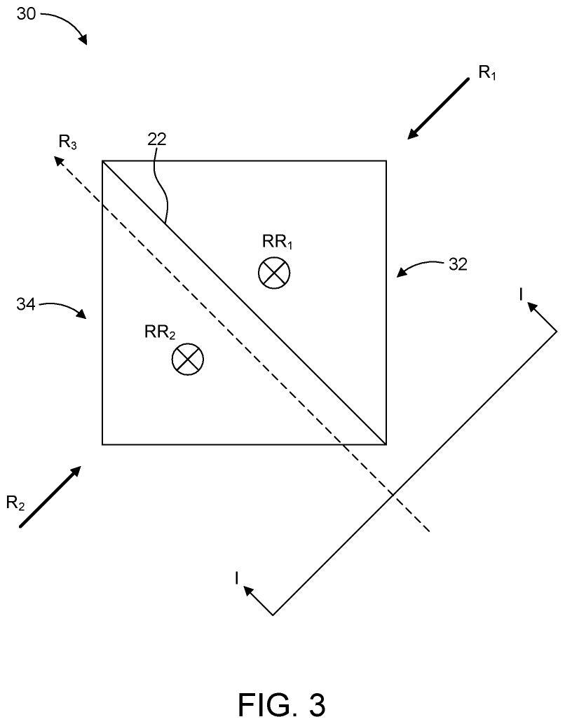

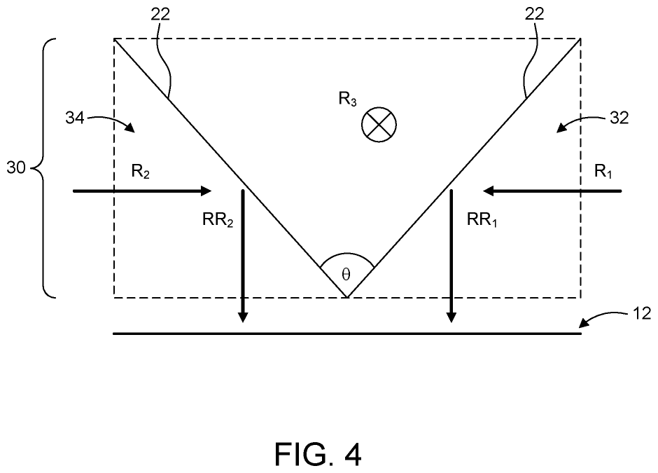

FIG. 3 shows a second embodiment of a transparent separator 30 viewed from a plan perspective. Transparent separator 30 includes first triangular section 32, second triangular section 34 and reflecting surface 22. First and second triangular sections 32 and 34 are made from a transparent material, in the visible light spectrum, as discussed above. First and second triangular sections 32 and 34 are also angled downward, as shown in FIG. 4 which shows a cross sectional view of the transparent separator 30. FIG. 4 is a cross sectional view taken along the line I-I, as shown in FIG. 3. As shown in FIG. 4, the first and second triangular sections 32 and 34 meet to form an angle θ. This angle is preferably 45°, but can also be other angles greater than or less than 45° so long as incoming light is directed downward toward the solar cell 12.

Returning to FIG. 3, light ray R₁ is shown entering the transparent separator 30 from an upper right direction. Light ray R₁ enters the transparent separator 30 and then reflects off of the reflecting surface 22. After the light ray R₁ reflects off of the reflecting surface 22, it is directed in a downward direction, toward a solar cell 12. This is shown by the reflected light ray RR₁ of FIG. 3, which is reflected in a downward direction. The cross sectional view in FIG. 4 also shows the reflected light ray RR₁ and its impingement upon the solar cell 12.

Light ray R₂ also follows a similar path as light ray R₁, except from an opposite direction. As shown in FIG. 3, light ray R₂ enters the transparent separator from a lower left direction and impinges upon reflecting surface 22. This causes the light ray R₂ to change direction and continue its path downward, toward the solar cell 12, as shown in FIG. 4. This is shown by the reflected light ray RR₂, which is reflected in a downward direction.

FIG. 3 also shows light ray R₃, which is passing through the transparent separator, parallel to the reflecting surface 22. Light ray R₃ is therefore uncaptured light, which doesn't allow the transparent separator to achieve its maximum efficiency of capturing light and directing it to the solar cell 12.

As indicated above, FIG. 4 is cross sectional view of the transparent separator 30 taken along the line I-I as shown in FIG. 3. As shown in FIG. 4, light ray R₁ enters the transparent separator 30 from a right direction and impinges the reflecting surface 22. The reflected light ray RR₁ is then directed in downward direction toward the solar cell 12.

Conversely, light ray R₂ enters the transparent separator 30 from a left direction and impinges the reflecting surface 22. The reflected light ray RR₂ is then directed in a downward direction toward the solar cell 12. Light ray R₃ is shown traveling through the transparent separator 30 in a direction that is parallel to the reflecting surfaces 22. Thus, light ray R₃ is not redirected toward the solar cell 12.

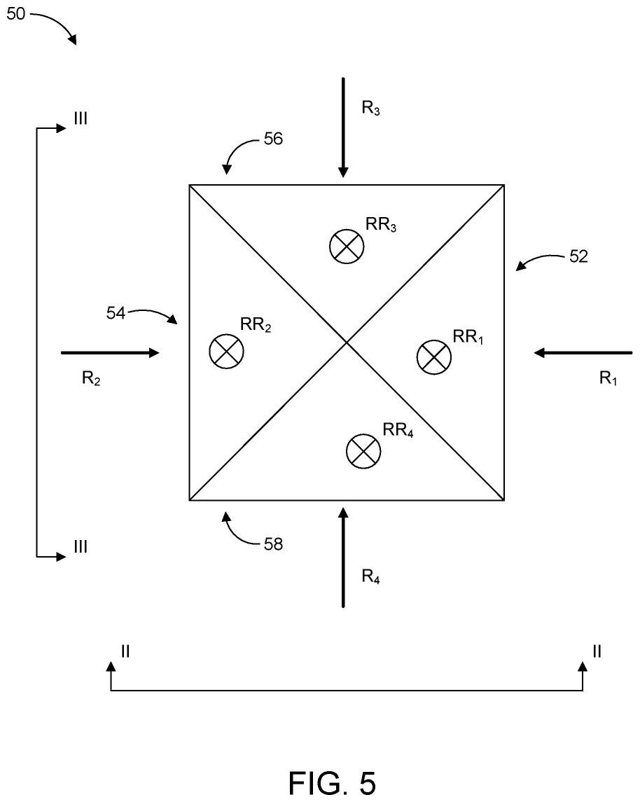

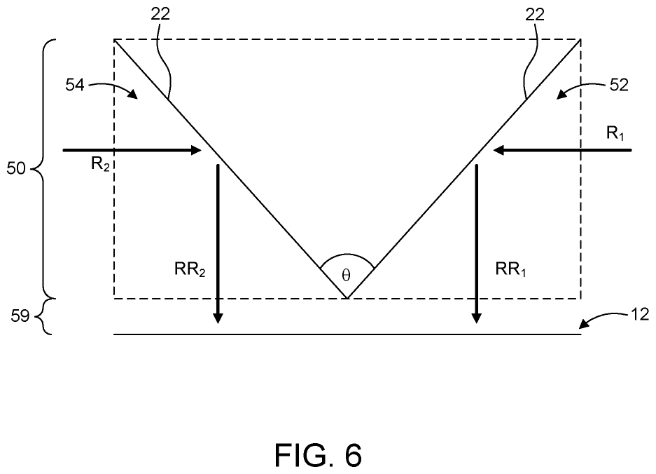

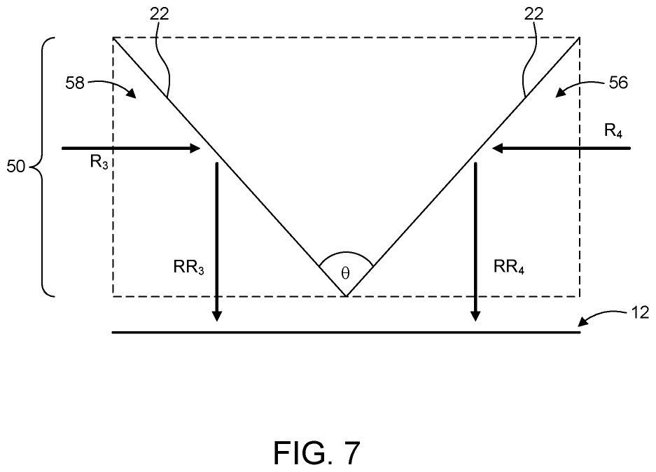

FIG. 5 shows an example of a third embodiment of a transparent separator 50. FIG. 5 is a plan view of a transparent separator 50. As shown in FIG. 5, the transparent separator 50 has four triangular sections 52, 54, 56 and 58. These triangular sections form a 4-sided pyramid. FIGS. 6 and 7 provide a cross sectional view taken along the line II-II and III-III respectively. Triangular sections 52, 54, 56 and 58 are made from a transparent material, in the visible light spectrum, as discussed above. It is noted that the embodiment is not limited to a 4 sided pyramid shape, but could also be a 3 sided pyramid shape, a 5 sided pyramid shape, a 6 sided pyramid shape, a conical shape, etc. Further, the sides of the pyramid/conical shape need not be perfectly flat. A concave or convex surface could be used. For example, a parabolic or hyperbolic surface could be used. Further, any transparent separator 50 which can direct light downward toward a solar cell 12 can be used.

As shown in FIG. 5, light rays R₁, R₂, R₃, and R₄ each approach the transparent separator from different directions. Specifically, light ray R₁ approaches from a right side direction, light ray R₂ approaches from a left side direction, light ray R₃ approaches from an upper direction and light ray R₄ approaches from a lower direction. It is noted that FIG. 5 is a plan view, and an upper direction and lower direction are not above or below the transparent separator, but are on a same or similar plane with respect to light rays R₁ and R₂.

Further, the light rays R₁, R₂, R₃, and R₄ do not necessarily have to be on the same plane as the solar cell 12. The light rays could be tilted or directed in a more upwards or downwards direction with respect to the plane formed by the solar cell 12.

Light ray R₁ enters the transparent separator 50 from a right side and impinges upon a reflecting surface 22. The reflected light ray RR₁ is then moving in a downward direction, toward the solar cell 12, as shown in FIG. 6. Light ray R₂ enters the transparent separator 50 from a left side and impinges upon a reflecting surface 22. The reflected light ray RR₂ is then moving in a downward direction, toward the solar cell 12, as shown in FIG. 6. Light ray R₃ enters the transparent separator 50 from an upper side and impinges upon a reflecting surface 22. The reflected light ray RR₃ is then moving in a downward direction, toward the solar cell 12, as shown in FIG. 7. Light ray R₄ enters the transparent separator 50 from a lower side and impinges upon a reflecting surface 22. The reflected light ray RR₄ is then moving in a downward direction, toward the solar cell 12, as shown in FIG. 7.

Thus, the transparent separator 50 can redirect light coming in from a plurality of directions to a solar cell 12. This increases the efficiency of the solar cell 12, as well as the solar assembly 10.

FIG. 6 is a cross sectional view of the transparent separator 50, taken along the lines II-II, as shown in FIG. 5. As shown in FIG. 6, light ray R₁ enters the transparent separator 50 from a right direction and impinges the reflecting surface 22. The reflected light ray RR₁ is then directed in downward direction toward the solar cell 12.

Further, FIG. 6 also shows an airgap 59. Airgap 59 is a gap between transparent separator 50 and solar cell 12. Airgap 59 can be used for cooling to the solar cell 12 by allowing heat to be transmitted to the surrounding air more easily. Airgap 59 is optional and a solar cell assembly could also be constructed without an airgap 59 between the transparent separator and the solar cell. Further, airgaps could exist between some of the transparent separators and solar cells and not between other transparent separators and solar cells.

Conversely, light ray R₂ enters the transparent separator 50 from a left direction and impinges the reflecting surface 22. The reflected light ray RR₂ is then directed in downward direction toward the solar cell 12. The angle θ, where the reflecting surfaces 22 meet, is preferably 45°, but can be more or less depending on the incoming angle of the light rays desired to be redirected toward the solar cell 12.

FIG. 7 is a cross sectional view of the transparent separator 50, taken along the lines III-III, as shown in FIG. 5. As shown in FIG. 7, light ray R₄ enters the transparent separator 50 from a right direction and impinges the reflecting surface 22. The reflected light ray RR₄ is then directed in downward direction toward the solar cell 12.

Conversely, light ray R₃ enters the transparent separator 50 from a left direction and impinges the reflecting surface 22. The reflected light ray RR₃ is then directed in downward direction toward the solar cell 12. The angle θ, where the reflecting surfaces 22 meet, is preferably 45°, but can be more or less depending on the incoming angle of the light rays desired to be redirected toward the solar cell 12.

The transparent separator can be generally rectangular in shape, including a square shape. The generally rectangular transparent separator can also have the corner cut at a 45° angle. The transparent separator could also have a generally circular shape. The shape of the transparent separator is not limited except that it is preferable that the transparent separator in a solar cell assembly 10 all have a generally consistent shape. Further, it is also preferable that the shape of the transparent separator generally matches that of the solar cells.

FIG. 8A shows another embodiment using a transparent separator 20. Although FIG. 8A shows transparent separator 20, any of the transparent separators 30, 50, etc. could also be used in a similar fashion. FIG. 8A shows a plan view of the transparent separator 20, with air gap standoffs 82A, 82B, 82C and 82D, located at the corners of the transparent separator. The embodiment is not limited to having the air gap standoffs in the corners of the transparent separator, and the air gap standoffs could be located at different points on the transparent separator, such as in the center, along the edges, randomly position, or systematically positioned, such as in a matrix or in parallel, etc. The air gap standoffs 82, provide separation between the transparent separator and an adjacent solar cell 12, and allow air to reach the solar cells 12. This allows heat to be dissipated more efficiently into the air.

The air gap standoffs 82 can be made from the same material as the transparent separator, or any other suitable material, and can be made as one unit, or can be glued or otherwise attached to the transparent separator (and solar cell) in any appropriate manner. The air gap standoffs 82 could also be a scaled down version of a transparent separator itself.

FIG. 8B shows a cross-sectional view of the transparent separator 20 and standoffs 82A and 82C, taken along the line IV-IV, as shown in FIG. 8A. The standoffs 82 can be a similar height to the thickness of the transparent separator. However, the height of the standoffs is not limited to this, and can be taller or shorter than the thickness of the transparent separator. Further, the standoffs 82 are not limited to a square shape, but could also have a rectangular, circular, or other shape.

In the example shown in FIGS. 8A and 8B, standoffs 82 are located on one side of the transparent separator 20. However, as shown in FIG. 8C, the standoffs 82A, 82C, 82E and 82F are located on a top and bottom side of the transparent separator 20. This allows for a greater airflow over an adjacent solar cell 12, so that air can contact both the top and bottom of a solar cell 12. For example, as shown in FIG. 8D, a top of solar cell 12 is adjacent to air gap standoffs 82A and 82C, and a bottom of solar cell 12 is adjacent to air gap standoffs 82G and 82H. This ensures two air gaps 84, which are located above and below solar cell 12. This allows heat to be dissipated more quickly, and the solar cells 12 to operate at a lower temperature, which can help to increase solar cell efficiency.

### Display Panel Design Using Light Channeling Stacked Solar Cells

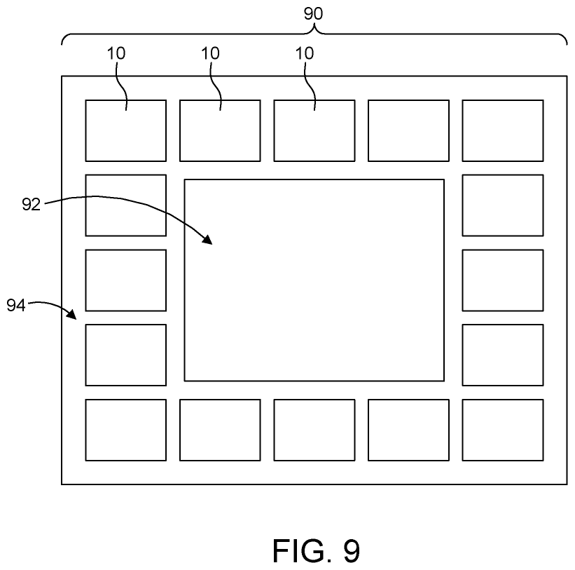

FIG. 9 shows an embodiment of the invention using a plurality of solar cell assemblies 10, referred to as solar cell array 90. As discussed above, a number of solar cells 12 and transparent separators 50 can be stacked together, as shown in FIG. 1, to form a solar cell assembly 10. However, a determination must be made as to how many solar cells 12 and transparent separators 50 to use in each solar assembly 10 and how many solar cell assemblies 10 to use altogether to power the intended device, in this case, a display screen.

For a number of solar cells n, there are (n−1) transparent separation layers. This is because the top solar cell does not need a transparent separator above it. Please see FIG. 1 for an example showing n=4, where there are four solar cells 12 and three transparent separators 50. For a given display panel design, there may exist design limitations prohibiting the vertical height of the solar cell assembly from exceeding a certain amount. With this height constraint in mind, the number of solar cells 12 in each solar cell assembly 10, depends on the calculations as discussed below.

Assuming that a thickness of the solar cell 12 is 1 unit thick, and the thickness of the transparent separator 50 is also 1 unit thick, the vertical height of the solar cell assembly SAₕ, is 2n−1, where n is the number of solar cells. Thus, if there are 5 solar cells, the thickness of the solar cell assembly 10, is (2×5)−1, for a total thickness of nine units or 9 times the thickness of a single solar cell.

Working backwards from the maximum height constraint of the solar cell assembly, the maximum number of solar cells in the solar assembly is:

$$n = \frac{{SA}_{h} + 1}{2} \qquad Formula 3$$

Thus, for a height restriction of nine thicknesses of a solar cell 12, this would equal 5 solar cells. If there was an even number of thicknesses of the solar assembly height, such as 8, this would yield 4.5 solar cells in the solar cell assembly. The number of solar cells in the solar cell assembly could be rounded down to the next whole number to ensure that the height restriction was not exceeded.

One solar cell assembly with the solar cells connected in series, would have a voltage generating capability of:

V_{assembly}=n×V_{cell} Formula 4:

If the display panel has a voltage requirement of Vₚₐₙₑₗ, then the required number of solar cells in a solar cell assembly would be:

$$n = \frac{{V}_{panel}}{{V}_{cell}} \qquad Formula 5$$

If a solar cell has a current generating capability of I_{cell}, then the serially connected solar cell assemblies would have the same current generating capability as that of an individual solar cell:

I_{assembly}=I_{cell} Formula 6:

If the display panel has a current requirement of Iₚₐₙₑₗ, then the parallel connected solar cell assemblies 10 would have a current generating capability of:

Iₚₐₙₑₗ=N_{assemblies}×I_{assembly} Formula 7:

The solar cell assemblies 10, could for example, be positioned on an outer perimeter of a display panel, as shown in FIG. 8. However, space can exist in between the solar cell assemblies 10 in order to allow light to enter from the side of the solar assemblies and not be blocked by adjacent solar assemblies.

FIG. 9 shows an example of how the solar cell assemblies can be configured to have space between the solar cell assemblies to allow additional light enter the solar cell assemblies.

Additionally, solar cells to need to dissipate heat in order to maintain efficient operation, and avoid an unnecessary decrease in lifespan. Embodiments of the invention can include providing a “clear air” channel in the lower half of the transparent separation layer. This would allow the solar cell assemblies to more efficiently dissipate heat.

### Display Panel Design Example

In this section, an example of using a solar cell array 90 to power a display panel design is described. An example solar cell from Aoshike™ has been selected that has the following specifications:

TABLE 1

| | | |
|---|---|---|
| Voltage | 0.5 | V |
| Current | 0.4 | A |
| Width | 19 | mm |
| Length | 52 | mm |

| | |
|---|---|
| Height | 0.25 mm to 0.5 mm |

The display panel 92, chosen as the example for powering with a group of solar cell assemblies is an Apple™ iPad Mini 4 tablet. The power requirements for this device are 5.2 volts, 2.4 amperes for a total power consumption of approximately 12 watts.

Setting aside any height constraints for the solar cell assemblies, the number of solar cells for a solar cell assembly that can meet voltage requirements of the display panel may be calculated as follows. Using formula 5 above, and setting Vₚₐₙₑₗ=V_{assembly}, the number of solar cells needed for a solar cell assembly can be determined as shown below:

$$n = \frac{{V}_{panel}}{{V}_{1}} = \frac{5.2 V}{0.5 V} = 10.4$$

Thus, in order to generate the required voltage levels, a stack of 11 solar cells would be required (with 10 transparent separation layers). It is noted that 10.4 solar cells can be rounded up to 11 to ensure the proper voltage requirement is met. This solar cell assembly would generate 0.4 amperes at 5.5 volts. The solar cell assembly dimensions would be 52 mm long and 19 mm wide, according to the solar cell specifications in Table 1. This would yield an area of 988 mm². While the present embodiment is not limited to this size, the footprint of the solar cell assembly should be able to fit on or around a display used for a copy machine, for example. The solar cell according to Table 1 is 0.5 mm thick, and therefore having 11 solar cells in an assembly, yields a total thickness of 5.5 mm.

Assuming the height of a transparent separator to be equal to the height of a solar cell, this would be a height of 0.5 mm. Multiplying by 10 transparent separators, this yields a height of 5 mm. Thus, the total combined height of the solar cell assemblies would be approximately 10.5 mm. Further, the solar cell assemblies can be positioned around an outer periphery of the display panel 92, as shown in FIG. 9.

Next, the number of solar cell assemblies needed to meet the current requirements of the display panel 92 can be determined as follows. Using formula 7 above:

$${N}_{assemblies} = \frac{{I}_{panel}}{{I}_{assembly}} = \frac{2.4 A}{0.4 A} = 6$$

Thus, in order to generate the required current levels to power the display panel, a set of 6 solar cell assemblies would be required. The combination of 6 solar cell assemblies, with each assembly having 11 solar cells, solar cell array 90, would generate 5.5 volts and 2.4 amperes for a total of 13.2 watts.

Further, solar cells are known to experience a drop in voltage and current generating capacity under load. Additional solar cells in the solar cell assembly, as well as additional solar cell assemblies could be included to account for the drop in performance under load. As each solar cell has different performance characteristics, the addition of solar cells in the solar cell assemblies and the addition of solar cell assemblies can be based on the individual solar cells being used.

Furthermore, the solar cells 12 and the transparent separator 50 may be positioned in the solar cell assembly 10 using a physical device such as a rack. The rack could allow separation between the solar cells 12 and the transparent separator 50 if desired. Alternatively, the solar cells 12 could abut the transparent separators 50. A rack could allow the solar cells 12 and transparent separators 50 to be interchanged individually. This configuration is helpful if one of the solar cells 12 or transparent separators 50 experiences a defect or malfunction, or if the efficiency decreases.

Further, the solar cells 12 could be fixed to the transparent separators 50. This could be done through an adhesive such as epoxy or the like. Further, an airgap could also be generated by placing the adhesive on the corners of the solar cells 12 and transparent separators 50 so as to allow a gap between the layers.

A number of embodiments of the invention have been described. It should be understood that various modifications may be made without departing from the spirit and scope of the invention. For example, various forms of the flows shown above may be used, with steps re-ordered, added, or removed. Also, although several embodiments of authorizing a remote terminal or mobile device have been described, it should be recognized that numerous other applications are contemplated. Accordingly, other embodiments are within the scope of the following claims.

Only selected embodiments have been chosen to illustrate the present invention. To those skilled in the art, however, it will be apparent from the foregoing disclosure that various changes and modifications can be made herein without departing from the scope of the invention as defined in the appended claims. Furthermore, the foregoing description of the embodiments according to the present invention is provided for illustration only, and not for limiting the invention as defined by the appended claims and their equivalents.

What is claimed is:

1: A multifunctional peripheral (MFP) comprising:
a solar powered display screen, which functions as a control panel of the MFP, the solar powered display screen comprising:
a solar cell array which comprises:
a plurality of solar cell assemblies, each solar cell assembly comprising:
a plurality of solar cells; and
a plurality of transparent separators;
wherein the plurality of solar cells are stacked on top of one another, with a transparent separator in between each pair of solar cells; and
wherein each transparent separator has a generally rectangular shape when viewed in a plan view.

2: The multifunctional peripheral according to claim 1, wherein each transparent separator directs incoming light in a downward direction, toward one of the plurality of solar cells.

3: The multifunctional peripheral according to claim 1, wherein each transparent separator comprises a plurality of reflecting surface, each reflecting surface configured to reflect incoming light in a downward direction toward one of the plurality of solar cells.

4: The multifunctional peripheral according to claim 3, wherein each transparent separator has four reflecting surfaces.

5: The multifunctional peripheral according to claim 4, wherein each reflecting surface is set at a 45° angle with respect to a top surface of one of the plurality of solar cells.

6: The multifunctional peripheral according to claim 1, wherein the solar cells in each of the plurality of solar cell assemblies are arranged in series.

7: The multifunctional peripheral according to claim 6, wherein each solar cell assembly is connected in parallel.

8: The multifunctional peripheral according to claim 1, wherein an air gap exists between each solar cell and each transparent separator.

9: The multifunctional peripheral according to claim 8, wherein each of the plurality of solar cell assemblies have a gap between it and an adjacent solar cell assembly.

10: The multifunctional peripheral according to claim 5, wherein the reflecting surfaces form a 4-sided pyramid.

11: The multifunctional peripheral according to claim 1, wherein each transparent separator is made from one of the group consisting of fused quartz, polycarbonate resin and glass.

12: The multifunctional peripheral according to claim 1, wherein each solar cell assembly is configured to be positioned around an outer periphery of a display screen.

13: The multifunctional peripheral according to claim 12, wherein each of the solar cells and each of the transparent separators has an approximately equal shape and surface area.

14: The multifunctional peripheral according to claim 13, wherein the area of each of the plurality of solar cell assemblies is approximately less than or equal to 988 mm².

15: The multifunctional peripheral according to claim 6, wherein each of the plurality of solar cell assemblies is configured to output a voltage sufficient to meet a voltage requirement of a display screen.

16: The multifunctional peripheral according to claim 7, wherein the plurality of solar cell assemblies is configured to output a current sufficient to meet a current requirement of a display screen.

17: A solar powered display screen comprising:
a display screen; and
a plurality of solar cell assemblies, each solar cell assembly comprising:
a plurality of solar cells; and
a plurality of transparent separators;
wherein the plurality of solar cells are stacked on top of one another, with a transparent separator in between each pair of solar cells; and
wherein each transparent separator having a generally rectangular shape when viewed in a plan view.

18: The solar powered display screen according to claim 17, wherein each of the plurality of solar cell assemblies is configured to be positioned around an output periphery of the display screen.

19: The solar powered display screen according to claim 18, wherein the plurality of solar cell assemblies is configured to output a voltage and a current, which is sufficient to meet a voltage requirement and a current requirement of a display screen.

20: A multifunctional peripheral comprising:
a solar powered display screen functioning as a control panel; and
a plurality of solar cell assemblies, each solar cell assembly comprising:
a plurality of solar cells; and
a plurality of transparent separators;
wherein the solar cells are stacked on top of one another, with a transparent separator in between each pair of solar cells;
wherein each transparent separator has a generally square or rectangular shape when viewed in a plan view;
wherein each transparent separator has a reflecting surface which is configured to reflect light toward a surface of the solar cell which is below it; and
wherein the plurality of solar cell assemblies is configured to output a voltage and a current that are sufficient to meet a voltage requirement and a current requirement of the solar powered display screen.
